(19) United States
(12) Patent Application Publication
(10) Pub. No.: US 2026/0190834 A1
(43) Pub. Date: Jul. 2, 2026

(54) ORGANIC LIGHT EMITTING DISPLAY APPARATUS

(71) Applicant: LG Display Co., Ltd., Seoul (KR)

(72) Inventors: SunWoong Kim, Paju-si (KR); JuHun Min, Paju-si (KR); SeungSoo Yang, Paju-si (KR); DongUk Kim, Paju-si (KR)

(73) Assignee: LG Display Co., Ltd., Seoul (KR)

(21) Appl. No.: 19/407,464

(22) Filed: Dec. 3, 2025

(30) Foreign Application Priority Data
Dec. 30, 2024 (KR) 10-2024-0201271

(51) Int. Cl. H10K 59/80; H10K 59/35

(52) U.S. Cl. CPC H10K 59/8792; H10K 59/8722; H10K 59/879; H10K 59/351

(57) ABSTRACT

An organic light emitting display apparatus includes a substrate; a plurality of organic light emitting elements on the substrate; a light guide member disposed on the plurality of organic light emitting elements; and a visible light absorbing layer on the light guide member and absorbing external light entering the organic light emitting display apparatus. Further, the light guide member includes a plurality of convex lens arranged in an irregular lens pattern with grooves disposed between adjacent convex lens; and a filling layer disposed on the lens pattern and including a material having a higher refractive index than a refractive index of the convex lens.

### CROSS-REFERENCE TO RELATED APPLICATIONS

This application claims priority to Korean Patent Application No. 10-2024-0201271, filed on Dec. 30, 2024, which is hereby incorporated by reference as if fully set forth herein.

### BACKGROUND

### Field of the Invention

The present application relates to an organic light emitting display apparatus capable of reducing reflectance due to external light.

### Discussion of the Related Art

As the information society develops, interest in display apparatuses for displaying images and the demand for using them are increasing in various forms, and the display field has been developing rapidly, and in response, various lightweight and thin flat panel display apparatuses have been developed and are receiving attention. Recently, display apparatuses such as liquid crystal display apparatuses and organic light emitting display apparatuses are being utilized.

Organic light emitting display apparatuses are self-luminous display apparatuses that display images on a display panel by emitting light from an organic light emitting layer sandwiched between two electrodes. Therefore, unlike liquid crystal displays, organic light emitting display apparatuses do not require a separate light source such as a backlight unit, and can be manufactured as lightweight and thin. In addition, organic light emitting display apparatuses are advantageous in terms of power consumption due to low-voltage operation, and are also excellent in color implementation, response speed, viewing angle, and contrast ratio, and are thus attracting attention as next-generation display apparatuses.

Organic light emitting display apparatuses display images by having the internal light escape to the outside of the organic light-emitting display apparatus. Research is ongoing to increase the efficiency of the internal light. However, it is difficult to improve this due to the increased reflectivity caused by external light, so research is also being conducted to reduce the reflective visibility.

In addition, if an organic light-emitting display apparatus does not use a polarizing plate, a diffraction pattern occurs due to light reflected from the organic light-emitting display apparatus, and a resin layer containing a lens pattern or a diffusion agent can be used to remove this diffraction pattern. However, if a resin layer containing a lens pattern or a diffusion agent is used, a sandy phenomenon may occur.

Meanwhile, when light is incident from the outside of an organic light-emitting display apparatus (external light incident), reflection and refraction occur in each layer that constitutes the display panel, and due to the fluctuation deviation of the reflected or refracted light, a blurry area like sand sprinkled on the area near the point where the reflected external light is recognized can occur. This phenomenon is called the sandy phenomenon. Research is continuously being conducted to improve this sandy phenomenon.

### SUMMARY

One embodiment of the present invention is to provide an organic light emitting display apparatus with reduced reflectance due to external light.

Another embodiment of the present invention is to provide an organic light emitting display apparatus having a minimized or reduced occurrence of a sandy phenomenon due to a lens pattern.

The problems to be solved by the embodiments of the present application are not limited to the problems mentioned above, and other problems not mentioned can be clearly understood by a person having ordinary knowledge in the technical field to which the technical idea of the present application belongs from the description below.

In order to achieve the-described technical problem, one embodiment of the present invention provides an organic light emitting display apparatus, comprising: a substrate; a plurality of organic light emitting elements on the substrate; a light guide member disposed on the plurality of organic light emitting elements; and a visible light absorbing layer on the light guide member and absorbing external light entering the organic light emitting display apparatus, wherein the light guide member comprises a plurality of convex lens arranged in an irregular lens pattern with grooves disposed between adjacent convex lens; and a filling layer disposed on the lens pattern.

The visible light absorbing layer includes a first visible light absorber, and the first visible light absorber can be included in the visible light absorbing layer in a mass ratio of 0.1 wt % to 3.0 wt %. The first visible light absorber can include at least one of lead white ((PbCO₃)₂·Pb(OH)₂), zinc oxide (ZnO), barium sulfate (BaSO₄), lithophone (BaSO₄·ZnS), and tricalcium phosphate (Ca₃(PO₄)₂). The filling layer includes a first filling layer disposed in the plurality of grooves; a second filling layer disposed on the first filling layer; and a third filling layer disposed on the second filling layer, wherein the first visible light absorber is included in each of the first filling layer and the second filling layer, and the first visible light absorber can be included in a higher mass ratio in the first filling layer than in the second filling layer.

The first visible light absorber can be included in the first filling layer at a mass ratio of 1.5 wt % or more and less than 3.0 wt %, and the first visible light absorber can be included in the second filling layer at a mass ratio of 0.1 wt % or more and less than 1.5 wt %. The second filling layer can have a thickness of 1 μm or more, and the third filling layer can have a thickness of 2 to 25 μm.

The thickness of the first filling layer can be thinner than the maximum depth of the plurality of grooves. The organic light emitting display apparatus further includes a first adhesive member and a second adhesive member disposed on the first adhesive member, wherein the light guide member can be disposed between the first adhesive member and the second adhesive member. The organic light emitting display apparatus further includes an intermediate layer disposed between the first adhesive member and the light guide member, wherein the first visible light absorber is included in the intermediate layer and the lens pattern, respectively, and the first visible light absorber can be included in the lens pattern at a higher mass ratio than in the intermediate layer.

The first visible light absorber can be included in the intermediate layer at a mass ratio of 0.1 wt % or more and less than 1.5 wt %, and the first visible light absorber can be included in the lens pattern at a mass ratio of 1.5 wt % or more and less than 3.0 wt %. The first visible light absorber can be included in the lens pattern and the filling layer, respectively, and the first visible light absorber can be included in the filling layer at a higher mass ratio than in the lens pattern. The first visible light absorber can be included in the lens pattern at a mass ratio of 0.1 wt % or more and less than 1.5 wt %, and the first visible light absorber can be included in the filling layer at a mass ratio of 1.5 wt % or more and less than 3.0 wt %. The lens pattern can include a second visible light absorber, and the second visible light absorber can be disposed adjacent to the plurality of grooves.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a drawing showing an organic light-emitting display apparatus according to one embodiment of the present application.

FIG. 2 is a plan view showing the planar structure of the pixel illustrated in FIG. 1.

FIG. 3 is a cross-sectional view taken along line I-I′ of FIG. 2.

FIG. 4 is an enlarged view showing area A of FIG. 3.

FIG. 5 is a drawing showing another embodiment of the present invention.

FIG. 6 is a drawing showing another embodiment of the present invention.

FIG. 7 is a drawing showing another embodiment of the present invention.

FIG. 8 is a drawing showing another embodiment of the present invention.

FIG. 9 is a drawing showing another embodiment of the present invention.

FIG. 10 is a drawing showing another embodiment of the present invention.

FIG. 11 is an image showing a diffraction phenomenon and a sandy phenomenon according to a comparative example and an embodiment.

FIG. 12 is an image showing a diffraction phenomenon and a sandy phenomenon according to another comparative example and an embodiment.

### DETAILED DESCRIPTION OF THE DISCLOSURE

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary. In construing an element, the element is construed as including an error band although there is no explicit description. In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used. It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship. In the addition of reference numerals to the components of each drawing describing embodiments of the present disclosure, the same components can have the same sign as can be displayed on the other drawings.

In the embodiments of the present invention, the source electrode and the drain electrode are distinguished only for the convenience of explanation, and the source electrode and the drain electrode can be interchanged. The source electrode can become the drain electrode, and the drain electrode can become the source electrode. In addition, the source electrode of one embodiment can become the drain electrode in another embodiment, and the drain electrode of one embodiment can become the source electrode in another embodiment.

In some embodiments of the present invention, for convenience of explanation, the source region and the source electrode are distinguished, and the drain region and the drain electrode are distinguished, but the embodiments of the present invention are not limited thereto. The source region may be the source electrode, and the drain region may be the drain electrode. In addition, the source region may be the drain electrode, and the drain region may be the source electrode.

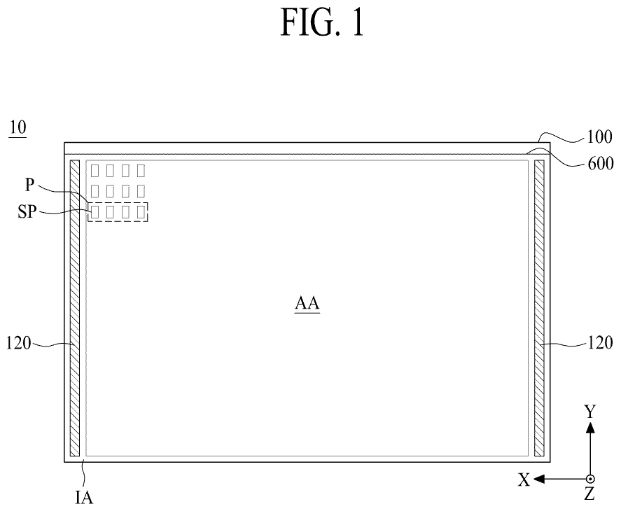

Next, FIG. 1 is a drawing showing an organic light-emitting display apparatus according to one embodiment of the present application. Referring to FIG. 1, the organic light-emitting display apparatus includes a display panel (10) including a substrate (100) and an opposing substrate (600) bonded to each other.

Also, the substrate (100) includes a thin film transistor and can be a transparent glass substrate or a transparent plastic substrate. The substrate (100) can also include a display area (AA) and a non-display area (IA). In particular, the display area (AA) is where an image is displayed, and can be a pixel array area, an active area, a pixel array portion, a display portion, or a screen. The display area (AA) can also include a plurality of pixels (P) disposed along each of a first direction (X) and a second direction (Y) crossing the first direction (X).

Each pixel (P) can include a plurality of adjacent subpixels (SP). As shown in FIG. 1, a plurality of subpixels (SP) can be included for a pixel (P). For example, the first direction (X) can be a first longitudinal direction, a long-side longitudinal direction, a horizontal direction, or a first horizontal direction of the substrate (100). Also, the second direction (Y) can be a second longitudinal direction, a short-side longitudinal direction, a vertical direction, a second horizontal direction, or a vertical direction of the substrate (100).

In addition, the non-display area (IA) is where an image is not displayed, and can be a peripheral circuit area, a signal supply area, an inactive area, or a bezel area. The non-display area (IA) can surround the display area (AA). Also, the display panel (10) or the substrate (100) can further include a peripheral circuit unit (120) disposed in the non-display area (IA). In particular, the peripheral circuit unit (120) can include a gate driving circuit connected to a plurality of subpixels (SP).

Further, the opposing substrate (600) can overlap the display areas (AA) and be bonded to the substrate (100) by using an adhesive (or transparent adhesive) to face the substrate (100) or can be disposed so that an organic or inorganic material is laminated on the substrate (100). The opposing substrate (600) can also be an upper substrate, a second substrate, or an encapsulating substrate, and can be used to encapsulating the substrate (100).

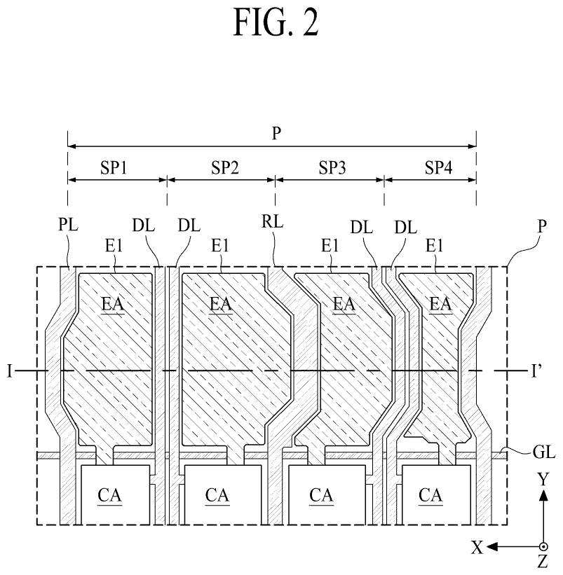

Next, FIG. 2 is a plan view showing the planar structure of the pixel illustrated in FIG. 1. Referring to FIGS. 1 and 2, in an organic light emitting display apparatus or display panel (10) according to one embodiment of the present application, each of a plurality of pixels (P) can include four subpixels (SP1 to SP4).

As shown, each pixel (P) can include first to fourth sub-pixels (SP1 to SP4) adjacent to each other along the first direction (X). For example, each pixel (P) can include a red first sub-pixel (SP1), a white second sub-pixel (SP2), a green third sub-pixel (SP3), and a blue fourth sub-pixel (SP4), but the embodiment of the present specification is not limited thereto. Each of the first to fourth sub-pixels (SP1 to SP4) can have different sizes (or areas) and include an emission area (EA) and a circuit area (CA).

In addition, the emission area (EA) can be disposed on one side (or upper side) of the sub-pixel area. Also, the emission area (EA) of each of the first to fourth sub-pixels (SP1 to SP4) can have a different size (or area). For example, the emission area (EA) can be an aperture area or an emission area. According to one embodiment, among the emission areas (EA) of the first to fourth subpixels (SP1 to SP4), the emission area (EA) of the second sub-pixel (SP2) can have the largest size, the emission area (EA) of the fourth sub-pixel (SP4) can have the smallest size, and the emission area (EA) of the first sub-pixel (SP1) can be smaller than the emission area (EA) of the second sub-pixel (SP2) and larger than the emission areas (EA) of the third and fourth subpixels (SP3, SP4). In addition, the emission area (EA) of the third sub-pixel (SP3) can have a larger size than the emission area (EA) of the fourth sub-pixel (SP4). However, the embodiments of the present application are not limited thereto.

Also, the circuit area (CA) of each of the first to fourth sub-pixels (SP1 to SP4) can be spatially separated from the emission area (EA) within the sub-pixel area. For example, the circuit area (CA) can be disposed on the other side (or lower side) of the sub-pixel area, but is not limited thereto. At least a portion of the circuit area (CA) can also overlap the emission area (EA) within the sub-pixel area. For example, the circuit area (CA) can overlap the entire emission area (EA) within the sub-pixel area or can be disposed below the emission area (EA). For example, the circuit area (CA) can be a non-emission area or a non-aperture area.

According to another embodiment, each pixel (P) can further include a light-transmitting portion disposed around at least one of the emission area (EA) and the circuit area (CA) of each of the first to fourth subpixels (SP1 to SP4). For example, each pixel (P) can include an emission area (EA) per pixel corresponding to each of the plurality of subpixels (SP1 to SP4) and a light-transmitting portion disposed around each of the plurality of subpixels (SP), and in this instance, an organic light emitting display apparatus can implement a transparent display apparatus due to the light transmission of the light transmitting portion.

As shown in FIG. 2, between the first sub-pixel (SP1) and the second sub-pixel (SP2), and between the third sub-pixel (SP3) and the fourth sub-pixel (SP4), two data lines (DL) extending along the second direction (Y) can be disposed in parallel with each other. Between the emission area (EA) and the circuit area (CA) of each of the first to fourth subpixels (SP1 to SP4), a gate line (GL) extending along the first direction (X) can be disposed. Also, a pixel power line (PL) extending along the second direction (Y) can be disposed on one side of the first sub-pixel (SP1) or the fourth sub-pixel (SP4). A reference line (RL) extending along the second direction (Y) can also be disposed between the second sub-pixel (SP2) and the third sub-pixel (SP3). In particular, the reference line (RL) can be used as a sensing line for externally sensing a change in the characteristics of a driving thin film transistor disposed in a circuit area (CA) and/or a change in the characteristics of a light-emitting element layer when the pixel (P) is in a sensing driving mode.

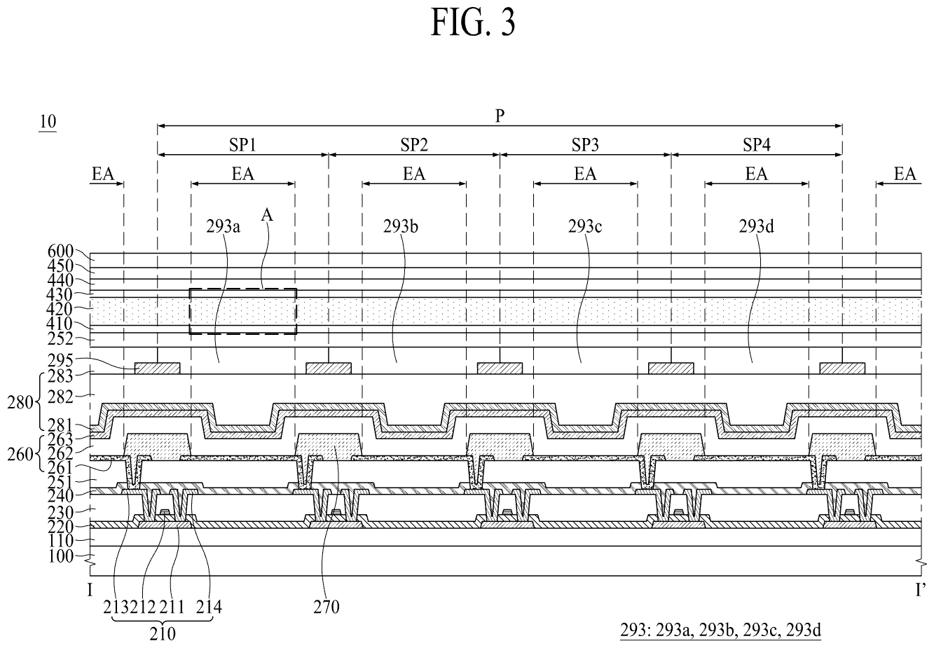

Next, FIG. 3 is a cross-sectional view taken along line I-I′ of FIG. 2. Referring to FIGS. 2 and 3, the organic light-emitting display apparatus can include a substrate (100) and an opposing substrate (600). For example, the organic light-emitting display apparatus or display panel (10) can include a substrate (100) and an opposing substrate (600). In particular, the substrate (100) includes a thin film transistor and can be a first substrate, a base substrate, a lower substrate, a transparent glass substrate, a transparent plastic substrate, or a base member.

Referring to FIG. 3, a buffer layer (110) can be disposed on a substrate (100). That is, the buffer layer (110) can be disposed on the entire first surface (or front surface) of the substrate (100). The buffer layer (110) thus can block a material contained in the substrate (100) from diffusing into the transistor layer during a high-temperature process during the manufacturing process of a thin film transistor, or can serve to prevent external moisture or humidity from penetrating toward the organic light emitting element (260). The buffer layer (110) can also be formed of a plurality of inorganic films that are alternately laminated. For example, the buffer layer (110) can be formed as a multi-film in which one or more inorganic films of a silicon oxide film (SiOx), a silicon nitride film (SiNx), and a silicon oxynitride film (SiON) are alternately laminated. The buffer layer (110) can be omitted.

Referring again to FIG. 3, thin film transistors (210) are formed on the buffer layer (110). Each of the thin film transistors (210) includes an active layer (211), a gate electrode (212), a source electrode (213), and a drain electrode (214). In FIG. 3, the thin film transistor (210) is exemplified as being formed in a top gate structure in which the gate electrode (212) is disposed on the active layer (211), but the present invention is not limited thereto. That is, the thin film transistors (210) can be formed in a bottom gate structure in which the gate electrode (212) is disposed below the active layer (211), or in a double gate structure in which the gate electrode (212) is disposed both above and below the active layer (211).

As shown in FIG. 3, an active layer (211) is formed on the buffer layer (110). In particular, the active layer (211) can be formed of a silicon-based semiconductor material or an oxide-based semiconductor material. A light-blocking layer can also be formed between the buffer layer (110) and the active layer (211) to block external light incident on the active layer (211). Further, a gate insulating film (220) can be formed on the active layer (211) and can be formed of an inorganic film, for example, a silicon oxide film (SiOx), a silicon nitride film (SiNx), or a multi-film thereof.

In addition, a gate electrode (212) and a gate line can be formed on the gate insulating film (220). The gate electrode (212) and the gate line can be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof. An interlayer insulating film (230) can also be formed on the gate electrode (212) and the gate line and can be formed of an inorganic film, for example, a silicon oxide film (SiOx), a silicon nitride film (SiNx), or a multi-film thereof.

Also, a source electrode (213), a drain electrode (214), and a data line can be formed on the interlayer insulating film (230). As shown, each of the source electrode (213) and the drain electrode (214) can be connected to the active layer (211) through a contact hole penetrating the gate insulating film (220) and the interlayer insulating film (230). The source electrode (213), the drain electrode (214), and the data line can be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

In addition, a protective film (240) for insulating the thin film transistor (210) can be formed on the source electrode (213), the drain electrode (214), and the data line. The protective film (240) can be formed of an inorganic film, for example, a silicon oxide film (SiOx), a silicon nitride film (SiNx), or a multi-film thereof. As shown, a flattening portion (251) can be formed on the protective film (240) to flatten the step caused by the thin film transistor (210). The flattening portion (251) can be formed of an organic film such as an acrylic resin, an epoxy resin, a phenolic resin, a polyamide resin, or a polyimide resin.

An organic light-emitting element (260) and a bank (270) are also formed on a flattening portion (251). As shown in FIG. 3, the organic light-emitting element (260) includes a first electrode (261), an organic light emitting layer (262), and a second electrode (263). In particular, the first electrode (261) can be an anode electrode, and the second electrode (263) can be a cathode electrode. The first electrode (261) can also be formed on the flattening portion (251). As shown, the first electrode (261) is connected to the source electrode (213) of the thin film transistor (210) through a contact hole penetrating the protective film (240) and the flattening portion (251). For a top-emitting method in which each of the pixels (P) outputs light toward the opposite substrate (600), the first electrode (261) can include a single-layer structure or a multi-layer structure made of one material selected from aluminum (Al), silver (Ag), molybdenum (Mo), gold (Au), magnesium (Mg), calcium (Ca), or barium (Ba), or two or more alloy materials.

In addition, the bank (270) can be formed to cover the edge of the first electrode (261) on the flattening portion (251) to define pixels (P). That is, the bank (270) serves as a pixel defining film that defines pixels (P). Each of the pixels (P) is a region in which a first electrode (261) corresponding to an anode electrode, an organic light-emitting layer (262), and a second electrode (263) corresponding to a cathode electrode are sequentially laminated, and holes from the first electrode (261) and electrons from the second electrode (263) are combined with each other in the organic light-emitting layer (262) to emit light. In this instance, the region in which the bank (270) is formed does not emit light and can therefore be defined as a non-light-emitting region.

Further, the bank (270) can be formed of an organic film such as an acrylic resin, an epoxy resin, a phenolic resin, a polyamide resin, or a polyimide resin. Also, an organic light emitting layer (262) is formed on the first electrode (261) and the bank (270). The organic light emitting layer (262) is a common layer formed in common on the pixels (P) and can be a white light-emitting layer that emits white light. In this instance, the organic light emitting layer (262) can be deposited using an open mask in which an opening is formed over the entire display area.

When the organic light emitting layer (262) is formed as a common layer that emits white light, the organic light emitting layer (262) can be formed in a tandem structure of two or more stacks. Each of the stacks can include a hole transporting layer, at least one light emitting layer, and an electron transporting layer.

Additionally, a charge generation layer can be formed between the stacks and can include an n-type charge generation layer disposed adjacent to the lower stack and a p-type charge generation layer formed on the n-type charge generation layer and disposed adjacent to the upper stack. The n-type charge generation layer injects electrons into the lower stack, and the p-type charge generation layer injects holes into the upper stack. The n-type charge generation layer can be an organic layer with an alkali metal such as Li, Na, K, or Cs, or an alkaline earth metal such as Mg, Sr, Ba, or Ra doped into an organic host material having electron transport capability. The p-type charge generation layer can be an organic layer with a dopant doped into an organic host material having hole transport capability.

Further, the second electrode (263) is formed on the organic light-emitting layer (262) and is a common layer formed in common on the pixels (P). The second electrode (263) can also be formed of a transparent metal material (TCO) such as ITO or IZO that can transmit light, or a semitransmissive metal material such as magnesium (Mg), silver (Ag), or an alloy of magnesium (Mg) and silver (Ag).

Also, an encapsulation film (280) is disposed on the second electrode (263) to prevent oxygen or moisture from penetrating into the organic light-emitting layer (262) and the second electrode (263). The encapsulation film (280) can include at least one inorganic film and can further include at least one organic film to prevent foreign substances (particles) from being introduced into the organic light-emitting layer (262) and the second electrode (263). For example, the encapsulation film (280) can include a first inorganic film (281), an organic film (282), and a second inorganic film (283), as shown in FIG. 3.

In addition, the first inorganic film (281) is disposed on the second electrode (263) and can be formed to cover the second electrode (263). Further, the organic film (282) is disposed on the first inorganic film (281) and can be formed to a sufficient thickness to prevent the foreign substances (particles) from being introduced into the organic light-emitting layer (262) and the second electrode (263) through the encapsulation film (280) and the first inorganic film (281).

In addition, the second inorganic film (283) is disposed on the organic film (282) and can be formed to cover the organic film (282). Each of the first inorganic film (281) and the second inorganic film (283) can also be formed of silicon nitride, aluminum nitride, zirconium nitride, titanium nitride, hafnium nitride, tantalum nitride, silicon oxide, aluminum oxide, or titanium oxide.

Also, an organic light-emitting display apparatus according to one embodiment of the present invention includes a plurality of color filters (293) disposed on an organic light-emitting element (260). As an example, referring to FIG. 3, the plurality of color filters (293) can include a first color filter (293a), a second color filter (293b), a third color filter (293c), and a fourth color filter (293d). The color filters (293) can be disposed between the organic light emitting element (260) and the opposing substrate (600) to overlap at least one emission area (EA). Specifically, the color filters (293) can be disposed between the encapsulation film (280) and the light guide member (420).

Also, the color filters (293) can have a size wider than the emission area (EA). For example, edge portions of the color filters (293) can overlap with the bank (270). In addition, the color filters (293) can have a size corresponding to each sub-pixel (SP1, SP2, SP3, SP4), thereby reducing light leakage between adjacent subpixels (SP).

Further, the color filters (293) can transmit wavelengths of colors set for the sub-pixels (SP). For example, as illustrated in FIG. 2, when one pixel (P) is composed of first to fourth sub-pixels (SP1, SP2, SP3, and SP4), the first to fourth color filters (293a, 293b, 293c, and 293d) can include a red color filter provided in the first sub-pixel (SP1), a green color filter provided in the third sub-pixel (SP3), and a blue color filter provided in the fourth sub-pixel (SP4). The second sub-pixel (SP2) may not include a color filter layer or may include a transparent material for step compensation, thereby emitting white light. A black matrix (295) can also be disposed on the encapsulation film (280).

Further, as shown, the black matrix (295) is disposed at a boundary between adjacent organic light emitting elements (260). In particular, the boundary of the organic light emitting element (260) coincides with the boundary of the sub-pixel (SP1, SP2, SP3, SP4). That is, the black matrix (295) overlaps the boundary of the adjacent subpixels (SP1, SP2, SP3, SP4). Specifically, the black matrix (295) can be disposed on the same layer as the color filters (293). For example, referring to FIG. 3, the black matrix (295) is disposed between the adjacent color filters (293). In addition, the black matrix (295) can be disposed to overlap with the remaining area except for the emission area (EA) of each sub-pixel (SP). Specifically, the black matrix (295) can be disposed to correspond to the bank (270).

As shown in FIG. 3, a flattening film (252) can be disposed on the color filters (293) and can be made of the same material as the flattening portion (251). A first adhesive member (410) can also be disposed on the flattening film (252). For example, the first adhesive member (410) can be disposed between the flattening film (252) and the light guide member (420). Thus, the first adhesive member (410) can adhere an upper surface of the flattening film (252) and a lower surface of the light guide member (420). Further, the first adhesive member (410) can be a transparent adhesive layer or a translucent adhesive layer. For example, the first adhesive member (410) can be composed of any one of a pressure sensitive adhesive (PSA), an optical clear adhesive (OCA), an optical curable resin (OCR), or an ultraviolet resin.

The organic light emitting display apparatus in FIG. 3 also includes a light guide member (420) disposed on the first adhesive member (410). Specifically, the light guide member (420) can be disposed on the first adhesive member (410) and can be disposed between the first adhesive member (410) and the opposing substrate (600).

Further, the light guide member (420) can be coupled to the opposing substrate (600) via a second adhesive member (430). For example, the second adhesive member (430) can be disposed between the light guide member (420) and the opposing substrate (600).

In addition, the light guide member (420) improves a diffraction pattern caused by light reflected from the organic light-emitting display apparatus or display panel (10). For example, if an organic light-emitting display apparatus does not use a polarizing plate, a diffraction pattern phenomenon can be observed due to light reflected from the organic light-emitting display apparatus, which causes a deterioration in the display quality of the organic light-emitting display apparatus.

Further, the light guide member (420) can diffract and/or scatter external light incident from the outside through the opposing substrate (600) based on the principle of light refraction according to a cross-sectional shape having a difference in refractive index, or to redistribute (or re-disperse) the diffraction dispersion spectrum of reflected light generated by the organic light emitting element (260), etc. For example, the light guide member (420) can reduce the intensity of the diffraction dispersion spectrum of reflected light generated by the organic light emitting element (260), or redistribute the diffraction dispersion spectrum to greatly expand the size of the spectrum, thereby suppressing or minimizing the occurrence of a diffraction pattern phenomenon through mixing between adjacent spectra according to the diffraction orders of the reflected light.

Further, a second adhesive member (430) can be disposed on the light guide member (420 and can be made of the same material as the first adhesive member (410), or can be made of a different material. The second adhesive member (430) can also be disposed between the light guide member (420) and the visible light absorbing layer (440). Thus, the second adhesive member (430) can adhere the upper surface of the light guide member (420) and the lower surface of the visible light absorbing layer (440). Further, second adhesive member (430) can be a transparent adhesive layer or a semitransparent adhesive layer.

Also, a visible light absorbing layer (440) can be disposed on the second adhesive member (430). In particular, the visible light absorbing layer (440) can be disposed between the organic light emitting element (260) and the opposing substrate (600). Specifically, the visible light absorbing layer (440) can be disposed between the light guide member (420) and the opposing substrate (600).

Further, the visible light absorbing layer (440) can include a first visible light absorber. For example, the first visible light absorber can include at least one of lead white ((PbCO₃)₂·Pb(OH)₂), zinc oxide (ZnO), barium sulfate (BaSO₄), lithophone (BaSO₄·ZnS), and tricalcium phosphate (Ca₃(PO₄)₂). The visible light absorbing layer (440) can have an absorption rate of 1 to 30% in a wavelength range of 380 to 750 nm.

In addition, the first visible light absorber can be included in the visible light absorbing layer (440) at a mass ratio of 0.1 wt % to 3.0 wt %. Preferably, the first visible light absorber can be included in the visible light absorbing layer (440) at a mass ratio of 0.1 wt % to 2.0 wt %. For example, if the mass ratio of the first visible light absorber is less than 0.1 wt %, a problem can arise in which light absorption does not sufficiently occur.

In addition, when the mass ratio of the first visible light absorber is greater than 3.0 wt %, excessive light absorption occurs, causing a problem in which luminous efficiency or brightness is reduced. In general, when using multiple lens patterns to remove diffraction patterns, a sandy phenomenon can occur due to the irregularity (or non-regularity) of the multiple lens patterns. That is, the sandy phenomenon includes bright and dark parts appearing irregularly and as spots.

Thus, the sandy phenomenon appears blurry as the surface reflectivity of the organic light emitting display apparatus or display panel (10) becomes higher. Also, the sandy phenomenon can be improved as the surface reflectivity becomes higher. However, when the surface reflectivity becomes higher, the light reflected on the screen enters the viewer's eyes, making it difficult to see the screen.

Therefore, according to an embodiment of the present invention, when the internal reflectance of an organic light emitting display apparatus or display panel (10) is reduced, the sandy phenomenon can be improved without increasing the surface reflectance. For example, when light incident from the outside passes through the visible light absorbing layer (440) and is reflected inside the organic light emitting display apparatus, the internal reflectance can be reduced by the visible light absorbing layer (440). That is, by reducing the internal reflectance, irregular light scattering due to internal reflection is reduced, and the reflected light is distributed more consistently on the screen surface, so that the sandy phenomenon can be improved.

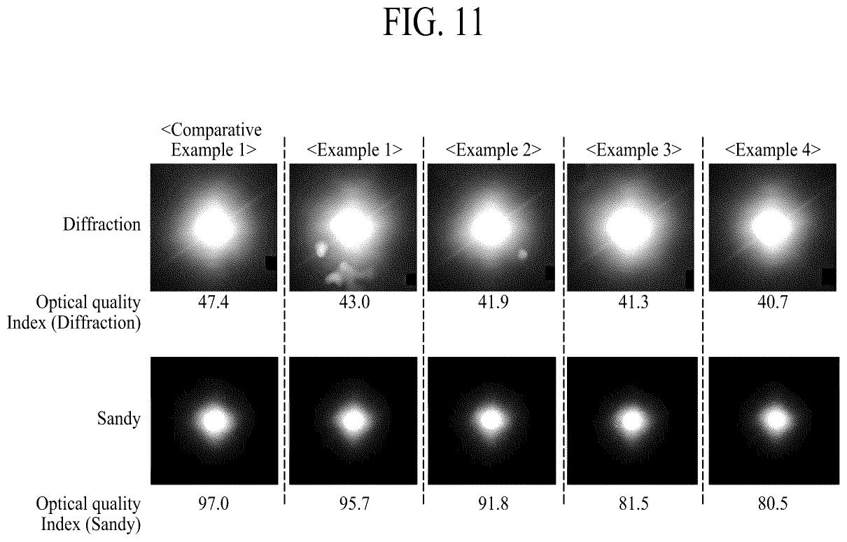

In more detail, FIG. 11 is an image showing a diffraction phenomenon and a sandy phenomenon according to Comparative Example 1 and an embodiment. Specifically, when the organic light-emitting display apparatus is in the off state, the reflected light is photographed when a point light source is shined on the organic light-emitting display apparatus. More specifically, the image of the diffraction phenomenon can be obtained by photographing while focusing on the point light source visible on the display panel (10), and the image of the sandy phenomenon can be obtained by photographing while focusing on the surface of the display panel (10). The point light source visible on the display panel (10) can be a virtual image.

In addition, the optical quality index of FIG. 11 means the average of the brightness difference between adjacent pixels on the entire display panel (10) based on the image data. Specifically, FIG. 11 shows the optical quality index in the image data of each of the diffraction phenomenon and the sandy phenomenon. A larger optical quality index means that the diffraction phenomenon and the sandy phenomenon are more prominent, and a smaller optical quality index means that the diffraction phenomenon and the sandy phenomenon are reduced.

Comparative Example 1 of FIG. 11 is an image showing the diffraction phenomenon and the sandy phenomenon in an organic light-emitting display apparatus that does not include a visible light absorbing layer (440). Because the organic light-emitting display apparatus of Comparative Example 1 does not include a visible light absorbing layer, the internal reflectance is not reduced. As a result, the diffraction phenomenon and the sandy phenomenon are prominently displayed.

In addition, examples 1 to 4 of FIG. 11 are images showing a diffraction phenomenon and a sandy phenomenon in an organic light emitting display apparatus including a visible light absorbing layer (440), respectively. In more detail, the organic light emitting display apparatuses of Examples 1 to 4 include a visible light absorbing layer having an absorption rate of 5%, 10%, 15%, and 30% in a wavelength range of 380 to 750 nm, respectively. Specifically, it can be seen that as the organic light-emitting display apparatus includes a visible light absorbing layer having a higher absorption rate in the wavelength range of 380 to 750 nm (for example, from 5% to 30%), the diffraction phenomenon and the sandy phenomenon are reduced.

Returning to FIG. 3, a third adhesive member (450) can be disposed on the visible light absorbing layer (440) and can be made of the same material as the first adhesive member (410) or a different material. Also, the third adhesive member (450) can be disposed between the light guide member (420) and the opposing substrate (600). In particular, the third adhesive member (450) can be disposed between the visible light absorbing layer (440) and the opposing substrate (600). Thus, the third adhesive member (450) can adhere the upper surface of the visible light absorbing layer (440) and the lower surface of the opposing substrate (600). The third adhesive member (450) can be a transparent adhesive layer or a semitransparent adhesive layer. The opposing substrate (600) can also be disposed on the third adhesive member (450).

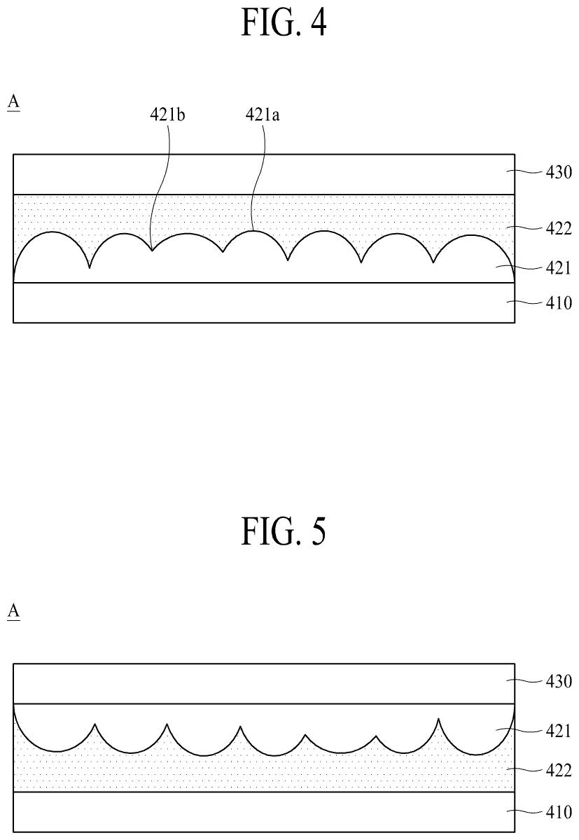

Next, FIG. 4 is an enlarged view showing area A of FIG. 3, And FIGS. 5-10 are drawings showing other embodiments of the present invention.

Referring to FIG. 4, the light guide member (420) can include a lens pattern (421) having an irregular arrangement structure and a filling layer (422). Specifically, the filling layer (422) is disposed on the lens pattern (421). More specifically, the filling layer (422) can be filled in a concave portion (or a valley portion) of the lens pattern (421).

Also, the lens pattern (421) can include a material having a first refractive index (n1), and the filling layer (422) can include a material having a second refractive index (n2) different from the first refractive index (n1) of the lens pattern (421). For example, the filling layer (422) can include a material having a higher refractive index than the refractive index of the lens pattern (421). More specifically, the refractive index difference between the first refractive index (n1) and the second refractive index (n2) can be 0.05 to 0.40.

Further, when the difference in refractive index between the first refractive index (n1) and the second refractive index (n2) is 0.05 to 0.40, the light guide member (420) including the lens pattern (421) and the filling layer (422) can suppress or minimize the occurrence of a diffraction pattern phenomenon through mixing between adjacent spectra according to the diffraction order of the reflected light by reducing the intensity of the diffraction dispersion spectrum of reflected light generated by the organic light-emitting element (260) or the like or by greatly expanding the size of the spectrum by redistributing the diffraction dispersion spectrum.

When the difference in refractive index between the first refractive index (n1) and the second refractive index (n2) exceeds 0.40, the occurrence of a diffraction pattern phenomenon due to reflection of external light can be reduced or suppressed, but the material reliability of the lens pattern (421) and the filling layer (422) can deteriorate. In addition, when the difference in refractive index between the first refractive index (n1) and the second refractive index (n2) is less than 0.05, even if the material reliability of the lens pattern (421) and the filling layer (422) is secured, a diffraction pattern phenomenon problem occurs due to reflection of external light.

Also, the lens pattern (421) include a plurality of convex lens (421a) and a plurality of grooves (421b) disposed between the convex lens (421a). Referring to FIG. 4, the filling layer (422) is disposed within the grooves (421b).

In particular, the convex lens (421a) are disposed toward the second adhesive member (430). Referring to FIGS. 3 and 4, the convex lens (421a) are disposed toward or facing the opposing substrate (600). In comparison with FIG. 4, FIG. 5 shows that a plurality of convex lens (421a) can be disposed toward the first adhesive member (410). Referring to FIGS. 3 and 5, the convex lens (421a) are disposed toward or to face the substrate (100).

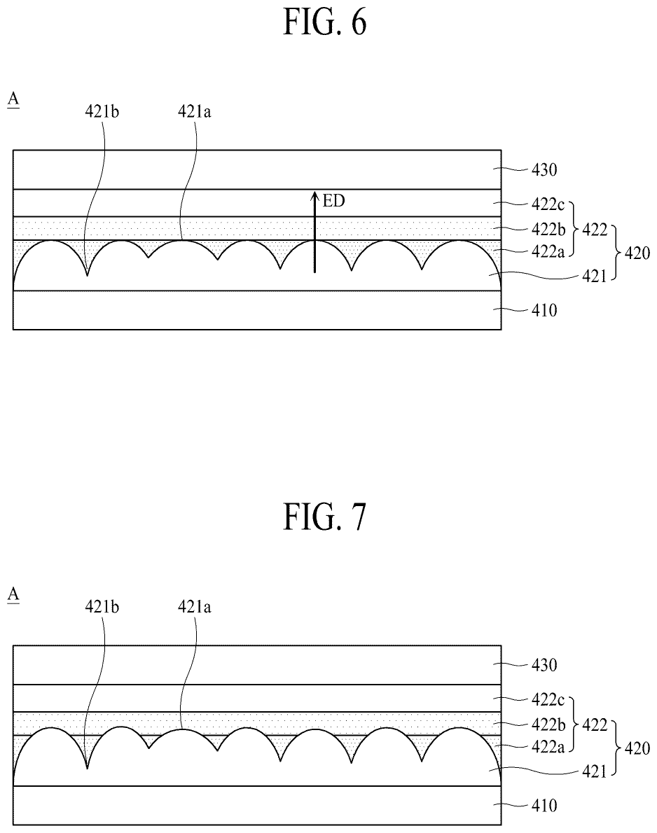

Further, as shown in FIG. 6, the filling layer (422) can include a first filling layer (422a), a second filling layer (422b), and a third filling layer (422c). For example, the first filling layer (422a) can be disposed in a plurality of grooves (421b). Thus, the thickness of the first filling layer (422a) can correspond to the depth of the grooves (421b). However, the present invention is not limited thereto, and the thickness of the first filling layer (422a) can be thinner than the maximum depth of the grooves (421b) (see FIG. 7).

Referring to FIG. 6, the second filling layer (422b) can be disposed on the first filling layer (422a). Specifically, the second filling layer (422b) can be disposed between the first filling layer (422a) and the third filling layer (422c). As shown in FIG. 6, the third filling layer (422c) can be disposed on the second filling layer (422b). Specifically, the third filling layer (422c) can be disposed between the second filling layer (422b) and the second adhesive member (430).

Further, the first visible light absorber can be included in each of the first filling layer (422a) and the second filling layer (422b). That is, the first filling layer (422a) and the second filling layer (422b) can each include the first visible light absorber. Specifically, the first visible light absorber can be included in a higher mass ratio in the first filling layer (422a) than in the second filling layer (422b).

In general, the normal direction in the convex lens (421a) can be perpendicular to the light emission direction (ED). In addition, the normal direction in the grooves (421b) can be close to parallel to the light emission direction (ED). Because the normal direction in the convex lens (421a) is perpendicular to the light emission direction (ED), the light can be brighter at the frontal viewing angle and darker at the side viewing angle. On the other hand, because the normal direction in the grooves (421b) is close to parallel to the light emission direction (ED), the light is refracted more, so the light can be brighter at the side viewing angle and darker at the frontal viewing angle. As a result, the bright and dark parts appear irregularly, which appear as spots possibly resulting in the sandy phenomenon.

Accordingly, one embodiment of the present invention can reduce the brightness of light in the grooves (421b) by including the first visible light absorber in a first filling layer (422a) disposed in the grooves (421b) with a high mass ratio, thereby suppressing the occurrence of the Sandy phenomenon. Further, since the second filling layer (422b) includes a first visible light absorber having a lower mass ratio than the first filling layer (422a), the brightness of light can be reduced, thereby suppressing the occurrence of the sandy phenomenon. In addition, the second filling layer (422b) can minimize the reduction in brightness. That is, if the second filling layer (422b) is absent, internal light absorption can be difficult, and if the second filling layer (422b) includes a first visible light absorber having a high mass ratio, a problem of reduced brightness can occur.

Further, the first visible light absorber can be included in the first filling layer (422a) at a mass ratio of 1.5 wt % or more and less than 3.0 wt %, and the first visible light absorber can be included in the second filling layer (422b) at a mass ratio of 0.1 wt % or more and less than 1.5 wt %. Preferably, the first visible light absorber can be included in the first filling layer (422a) at a mass ratio of 1.5 wt % or more and less than 2.0 wt %. When the first visible light absorber is included in the first filling layer (422a) at a mass ratio of less than 1.5 wt %, light absorption does not sufficiently occur.

In addition, when the first visible light absorber is included in the first filling layer (422a) in a mass ratio exceeding 3.0 wt %, excessive light absorption can occur, resulting in reduced brightness. When the first visible light absorber is included in the second filling layer (422b) at a mass ratio of less than 0.1 wt %, light absorption does not sufficiently occur. In addition, when the first visible light absorber is included in the second filling layer (422b) in a mass ratio exceeding 1.5 wt %, excessive light absorption can occur, resulting in reduced brightness.

Also, as shown in FIG. 6, uppermost surfaces of the convex lens 421a are disposed along a same height in the light guide member 420. In addition, the convex lens 421a convex perpendicular towards a viewing surface of the organic light emitting display apparatus as shown in FIG. 4. Alternatively, as shown in FIG. 5, the convex lens 421a convex perpendicular away from a viewing surface of the organic light emitting display apparatus. As shown in FIGS. 4-6, a first convex portion of a first convex lens has a different convex shape than a second convex portion of a second convex lens adjacent to the first convex lens, and a width of the first convex portion of the first convex lens is the same as a width of the second convex portion of a second convex lens adjacent to the first convex lens.

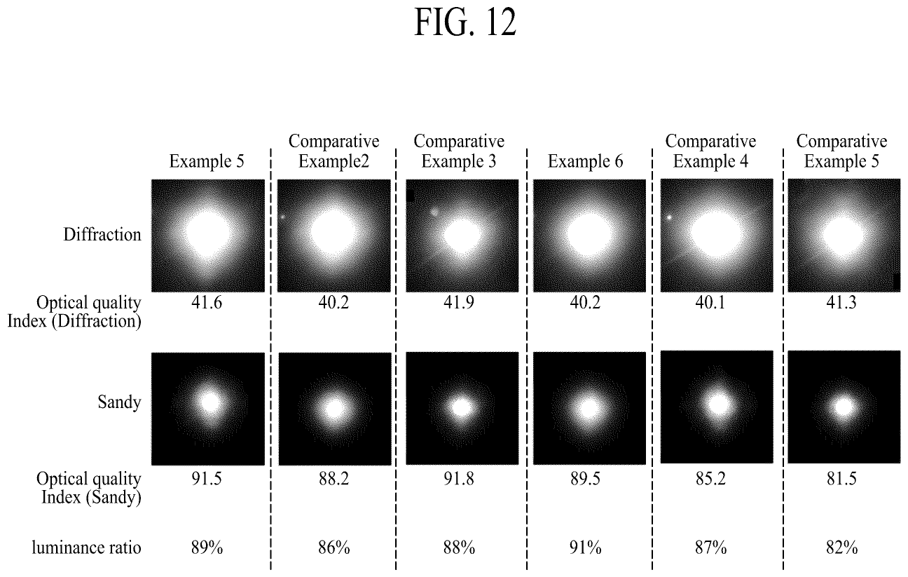

Next, FIG. 12 is an image showing a diffraction phenomenon and a sandy phenomenon according to a comparative example and an embodiment. Specifically, FIG. 12 is an image of light reflected when a point light source is shined on an organic light-emitting display apparatus when the organic light-emitting display apparatus is in the off state. The method of photographing the diffraction phenomenon and the sandy phenomenon overlaps with the description of FIG. 11 above.

Specifically, Example 5 and Comparative Examples 2 and 3 of FIG. 12 are distinguished according to the content of the first visible light absorber included in the first filling layer (422a) and the second filling layer (422b) in the organic light emitting display apparatus illustrated in FIG. 6. According to Example 5, the first visible light absorber is included in the first filling layer (422a) in an amount of 1.5 wt %, and the second filling layer (422b) in an amount of 0.5 wt %. According to Comparative Example 2, the first visible light absorber is included in the first filling layer (422a) in an amount of 0.5 wt %, and the second filling layer (422b) in an amount of 1.5 wt %. According to Comparative Example 3) the first visible light absorber is included in the first filling layer (422a) in an amount of 1.5 wt %, and the second filling layer (422b) in an amount of 1.5 wt %.

In the organic light emitting display apparatus of Example 5, the first visible light absorber is included in a higher mass ratio in the first filling layer (422a) than in the second filling layer (422b), so that the organic light emitting display apparatus can have a high luminance ratio even though it has a low optical quality index. In this instance, the luminance ratio means the ratio of the luminance of the organic light emitting display apparatus according to the Example or Comparative Example to the luminance of the organic light emitting display apparatus that does not include the layer including the first visible light absorber.

In the organic light-emitting display apparatus of Comparative Example 2, it can be seen that the first visible light absorber is included in a higher mass ratio in the second filling layer (422b) than in the first filling layer (422a), resulting in a low optical quality index, but a reduced luminance ratio. In the organic light-emitting display apparatus of Comparative Example 3, the first visible light absorber is included in the first filling layer (422a) and the second filling layer (422b) at the same mass ratio, so that it has a low optical quality index, but the luminance ratio is reduced.

Example 6 and Comparative Examples 4 and 5 of FIG. 12 are distinguished according to the content of the first visible light absorber included in the first filling layer (422a) and the second filling layer (422b) in the organic light emitting display apparatus illustrated in FIG. 7. For example, according to Example 6, the first visible light absorber is included in the first filling layer (422a) in an amount of 1.5 wt %, and the second filling layer (422b) in an amount of 0.5 wt %. According to Comparative Example 4, the first visible light absorber is included in the first filling layer (422a) in an amount of 0.5 wt %, and the second filling layer (422b) in an amount of 1.5 wt %. According to Comparative Example 5, the first visible light absorber is included in the first filling layer (422a) in an amount of 1.5 wt %, and the second filling layer (422b) in an amount of 1.5 wt %.

In the organic light emitting display apparatus of Example 6, the first visible light absorber is included in a higher mass ratio in the first filling layer (422a) than in the second filling layer (422b), so that it can have a high luminance ratio even though it has a low optical quality index. In the organic light-emitting display apparatus of Comparative Example 4, the first visible light absorber is included in a higher mass ratio in the second filling layer (422b) than in the first filling layer (422a), resulting in a low optical quality index, but a reduced luminance ratio. In the organic light-emitting display apparatus of Comparative Example 5, the first visible light absorber is included in the first filling layer (422a) and the second filling layer (422b) at the same mass ratio, so that it has a low optical quality index, but the luminance ratio is reduced.

Further, the first filling layer (422a) can have a light absorption rate of 5 to 10%, and the second filling layer (422b) can have a light absorption rate of 1 to 5%. Also, the range of the light absorption rate of the first filling layer (422a) may not overlap with the range of the light absorption rate of the second filling layer (422b). Further, the second filling layer (422b) can have a thickness of 1 μm or more, and the third filling layer (422c) can have a thickness of 2 to 25 μm. The second filling layer (422b) can also have a thickness of 1 μm or more to ensure sufficient light absorption. Further, the third filling layer (422c) can include an adhesive function and can have a thickness of 2 to 25 μm to increase the reliability of the adhesive. In addition, as shown in FIG. 7, the first filling layer (422a) is disposed in the grooves (421b) without covering the convex lens (421a). Also, the second filling layer (422b) is disposed on the first filling layer (422a) and covers the convex lens (421a).

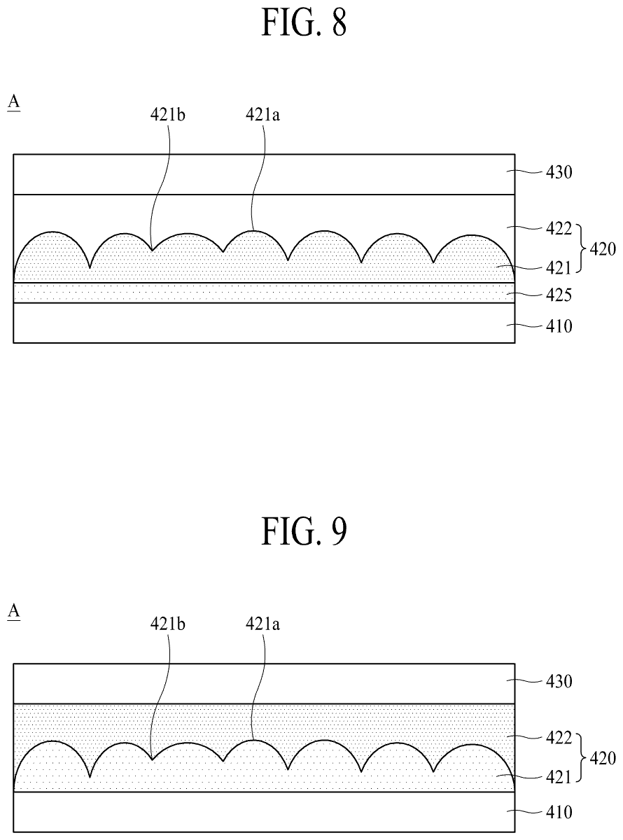

Referring to FIG. 8, the organic light emitting display apparatus according to an embodiment of the present invention can further include an intermediate layer (425) disposed between the first adhesive member (410) and the light guide member (420). Referring to FIG. 8, the first visible light absorber can be included in each of the intermediate layer (425) and the lens pattern (421). For example, the first visible light absorber can be included in a higher mass ratio in the lens pattern (421) than in the intermediate layer (425).

The present invention can reduce the brightness of light throughout the lens pattern (421) by including a first visible light absorber having a high mass ratio, thereby suppressing the occurrence of the sandy phenomenon. Further, because the intermediate layer (425) includes a first visible light absorber having a lower mass ratio than the lens pattern (421), the brightness of light can be reduced, thereby suppressing the occurrence of the sandy phenomenon. In addition, the intermediate layer (425) can minimize the reduction in brightness. That is, if the intermediate layer (425) is absent, internal light absorption can be difficult, and if the intermediate layer (425) includes a first visible light absorber having a high mass ratio, a reduced brightness can occur.

Further, the first visible light absorber can be included in the lens pattern (421) at a mass ratio of 1.5 wt % or more and less than 3.0 wt %, and the first visible light absorber can be included in the intermediate layer (425) at a mass ratio of 0.1 wt % or more and less than 1.5 wt %. Preferably, the first visible light absorber can be included in the lens pattern (421) at a mass ratio of 1.5 wt % or more and less than 2.0 wt %. When the first visible light absorber is included in the lens pattern (421) at a mass ratio of less than 1.5 wt %, light absorption does not sufficiently occur.

In addition, when the first visible light absorber is included in the lens pattern (421) in a mass ratio exceeding 3.0 wt %, excessive light absorption can occur, resulting in reduced brightness. When the first visible light absorber is included in the intermediate layer (425) at a mass ratio of less than 0.1 wt %, light absorption does not sufficiently occur. In addition, when the first visible light absorber is included in the intermediate layer (425) in a mass ratio exceeding 1.5 wt %, excessive light absorption can occur, resulting in reduced brightness.

Referring to FIG. 9, the first visible light absorber can be included in each of the lens pattern (421) and the filling layer (422). For example, the first visible light absorber can be included in a higher mass ratio in the filling layer (422) than in the lens patterns (421). Thus, the present invention can reduce the brightness of light on the upper portion of a lens pattern (421) by including a first visible light absorber with a high mass ratio in the filling layer (422), thereby suppressing the occurrence of the sandy phenomenon.

Further, because the lens pattern (421) includes a first visible light absorber having a lower mass ratio than the filling layer (422), the brightness of light can be reduced, thereby suppressing the occurrence of the sandy phenomenon. In addition, the lens pattern (421) can minimize the reduction in brightness. That is, if the lens pattern (421) includes a first visible light absorber having a high mass ratio, a reduction in brightness can occur.

Further, the first visible light absorber can be included in the filling layer (422) at a mass ratio of 1.5 wt % or more and less than 3.0 wt %, and the first visible light absorber can be included in the lens patterns (421) at a mass ratio of 0.1 wt % or more and less than 1.5 wt %. Preferably, the first visible light absorber can be included in the filling layer (422) at a mass ratio of 1.5 wt % or more and less than 2.0 wt %.

When the first visible light absorber is included in the filling layer (422) at a mass ratio of less than 1.5 wt %, insufficient light absorption can occur. In addition, when the first visible light absorber is included in the filling layer (422) in a mass ratio exceeding 3.0 wt %, excessive light absorption can occur, resulting in a reduced brightness.

When the first visible light absorber is included in the lens pattern (421) at a mass ratio of less than 0.1 wt %, light absorption does not sufficiently occur. In addition, when the first visible light absorber is included in the lens pattern (421) in a mass ratio exceeding 1.5 wt %, excessive light absorption can occur, resulting in a reduced brightness.

Further, the lens pattern (421) can include a second visible light absorber. For example, the second visible light absorber can include iron oxide. Specifically, the second visible light absorber can be a material affected by magnetism.

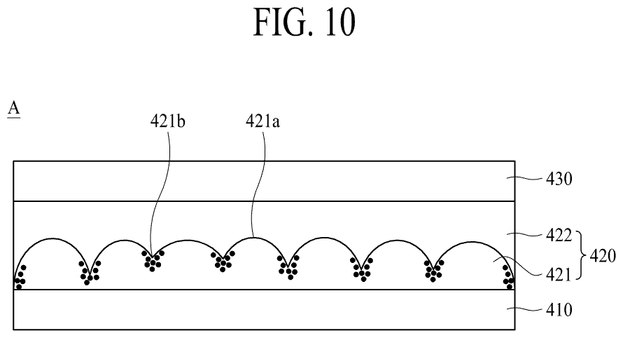

Referring to FIG. 10, the second visible light absorber can be disposed adjacent to the grooves (421b) of the lens pattern (421). According to an embodiment of the present invention, the lens pattern (421) is manufactured through a process of manufacturing a mold frame, etching the mold frame using a laser, applying resin to the mold frame, pressing the resin using a roller, and then hardening the resin.

In addition, according to FIG. 10, a magnetic force can be applied to the mold frame and the roller to place the second visible light absorber adjacent to the grooves (421b) of the lens pattern (421). Also, the magnetic force is concentrated on the non-etched relief portion of the mold frame, so that the second visible light absorber affected by the magnetism can be disposed adjacent to the grooves (421b).

Referring to FIG. 10, when the second visible light absorber is disposed adjacent to the grooves (421b) of the lens pattern (421), the brightness of light in the grooves (421b) can be reduced, thereby suppressing the occurrence of the Sandy phenomenon. In addition, the second visible light absorber being disposed adjacent to the grooves (421b) means that the second visible light absorber overlaps with the lowermost portion of the grooves (421b) and does not overlap with the uppermost portion of the convex lens (421a).

According to embodiment of the present disclosure, the following advantageous effects can be obtained. An organic light emitting display apparatus can reduce reflectance due to external light and can minimize or reduce the occurrence of a sandy phenomenon due to a lens pattern. In addition to the effects mentioned above, other features and advantages of the present invention are described below or may be clearly understood by those skilled in the art to which the present invention pertains from such description and explanation.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. An organic light emitting display apparatus, comprising:
a substrate;
a plurality of organic light emitting elements on the substrate;
a light guide member disposed on the plurality of organic light emitting elements; and
a visible light absorbing layer on the light guide member and absorbing external light entering the organic light emitting display apparatus,
wherein the light guide member includes:
a plurality of convex lens arranged in an irregular lens pattern with grooves disposed between adjacent convex lens; and
a filling layer disposed on the lens pattern.

2. The organic light emitting display apparatus of claim 1, wherein the visible light absorbing layer includes a first visible light absorber in a mass ratio of 0.1 wt % to 3.0 wt %.

3. The organic light emitting display apparatus of claim 2, wherein the first visible light absorber includes at least one of lead white ((PbCO₃)₂·Pb(OH)₂), zinc oxide (ZnO), barium sulfate (BaSO₄), lithophone (BaSO₄·ZnS), and tricalcium phosphate (Ca₃(PO₄)₂).

4. The organic light emitting display apparatus of claim 2, wherein the filling layer includes:
a first filling layer disposed in the grooves; and
a second filling layer disposed on the first filling layer;
wherein the first visible light absorber is included in each of the first filling layer and the second filling layer, and
wherein the first visible light absorber is included in a higher mass ratio in the first filling layer than in the second filling layer.

5. The organic light emitting display apparatus of claim 4, wherein the first filling layer is disposed in the grooves without covering the convex lens.

6. The organic light emitting display apparatus of claim 5, wherein the second filling layer is disposed on the first filling layer and covers the convex lens.

7. The organic light emitting display apparatus of claim 4, wherein the first visible light absorber is included in the first filling layer at a mass ratio of 1.5 wt % or more and less than 3.0 wt %, and
wherein the first visible light absorber is included in the second filling layer at a mass ratio of 0.1 wt % or more and less than 1.5 wt %.

8. The organic light emitting display apparatus of claim 4, wherein the filling layer includes a third filling layer disposed on the second filling layer.

9. The organic light emitting display apparatus of claim 8, wherein the second filling layer has a thickness of 1 μm or more, and the third filling layer has a thickness of 2 to 25 μm.

10. The organic light emitting display apparatus of claim 4, wherein a thickness of the first filling layer is thinner than a maximum depth of the grooves.

11. The organic light emitting display apparatus of claim 2, further comprising:
a first adhesive member and a second adhesive member disposed on the first adhesive member,
wherein the light guide member is disposed between the first adhesive member and the second adhesive member.

12. The organic light emitting display apparatus of claim 11, further comprising:
an intermediate layer disposed between the first adhesive member and the light guide member, and
wherein the first visible light absorber is included in the lens pattern at a higher mass ratio than in the intermediate layer.

13. The organic light emitting display apparatus of claim 12, wherein the first visible light absorber is included in the intermediate layer at a mass ratio of 0.1 wt % or more and less than 1.5 wt %, and the first visible light absorber is included in the lens pattern at a mass ratio of 1.5 wt % or more and less than 3.0 wt %.

14. The organic light emitting display apparatus of claim 2, wherein the first visible light absorber is included in the lens pattern and the filling layer, and the first visible light absorber is included in the filling layer at a higher mass ratio than in the lens pattern.

15. The organic light emitting display apparatus of claim 14, wherein the first visible light absorber is included in the lens pattern at a mass ratio of 0.1 wt % or more and less than 1.5 wt %, and the first visible light absorber is included in the filling layer at a mass ratio of 1.5 wt % or more and less than 3.0 wt %.

16. The organic light emitting display apparatus of claim 2, wherein the lens pattern includes a second visible light absorber disposed adjacent to the grooves.

17. The organic light emitting display apparatus of claim 16, wherein the second visible light absorber include iron oxide.

18. The organic light emitting display apparatus of claim 1, wherein uppermost surfaces of one or more of the convex lens are disposed along a same height in the light guide member.

19. The organic light emitting display apparatus of claim 1, wherein one or more of the convex lens convex perpendicular towards a viewing surface of the organic light emitting display apparatus.

20. The organic light emitting display apparatus of claim 1, wherein one or more of the convex lens convex perpendicular away from a viewing surface of the organic light emitting display apparatus.

21. The organic light emitting display apparatus of claim 1, wherein a first convex portion of a first convex lens has a different convex shape than a second convex portion of a second convex lens adjacent to the first convex lens, and
wherein a width of the first convex portion of the first convex lens is the same as a width of the second convex portion of the second convex lens adjacent to the first convex lens.

22. The organic light emitting display apparatus of claim 1, wherein a refractive index of the filling layer is different from a refractive index of the convex lens.
